(19) United States
(12) Patent Application Publication
(10) Pub. No.: US 2012/0260973 A1
(43) Pub. Date: Oct. 18, 2012

(54) BUSING SUB-ASSEMBLY FOR PHOTOVOLTAIC MODULES

(75) Inventors: John Telle, Albuquerque, NM (US); Brian J. Murphy, Albuquerque, NM (US); David H. Meakin, Albuquerque, NM (US)

(73) Assignee: APPLIED MATERIALS, INC., Santa Clara, CA (US)

(21) Appl. No.: 13/445,741

(22) Filed: Apr. 12, 2012

Related U.S. Application Data
(60) Provisional application No. 61/476,157, filed on Apr. 15, 2011.

(51) Int. Cl. H01L 31/048; H05K 1/00; H05K 1/09; H01L 31/18

(52) U.S. Cl. 136/251; 438/66; 174/250; 174/257; 174/258; 257/E31.114

(57) ABSTRACT

Embodiments of the invention generally relate to a busing sub-assembly and methods of forming photovoltaic modules having busing sub-assemblies. The busing sub-assembly generally includes a carrier backsheet and a plurality of conductive ribbons coupled to the carrier backsheet. An electrically insulating cover is disposed over the conductive ribbons and the carrier backsheet. The ends of each conductive ribbon remain exposed for making an electrical connection to the conductive foil or a junction box. Methods of forming photovoltaic modules generally include positioning a flexible backsheet having an opening therethrough and a conductive foil thereon on a support. A busing sub-assembly is disposed on the flexible backsheet over the opening and in electrical contact with the conductive foil. The busing sub-assembly includes the components necessary to bus electrical current from a plurality of solar cells to a junction box, and can be applied to a photovoltaic module in a singe process step.

### CROSS-REFERENCE TO RELATED APPLICATIONS

This application claims benefit of U.S. Provisional Patent Application Ser. No. 61/476,157, filed Apr. 15, 2011, which is herein incorporated by reference.

### BACKGROUND OF THE INVENTION

1. Field of the Invention

Embodiments of the present invention generally relate to busing assemblies for use in photovoltaic modules.

2. Description of the Related Art

Solar cells are photovoltaic devices that convert sunlight into electrical power. Each solar cell generates a specific amount of electric power and is typically tiled into an array of interconnected solar cells, also known as photovoltaic modules, that are sized to deliver a desired amount of generated electrical power. Busing ribbons are used to collect and transport the generated electrical power from one or more modules to one or more junction boxes, where the electrical power may then be utilized to power electronic devices. In typical modules, busing ribbon placement involves positioning and soldering each busing ribbon manually. To improve aesthetic appearance, a cover may also be manually positioned and adhered over the busing ribbons. The manual processing required to position the busing ribbons is time consuming and inefficient, and thus represents a sizeable manufacturing cost in the production of photovoltaic modules.

Therefore, there is a need for efficient and cost effective busing assemblies and methods of use in photovoltaic modules.

### SUMMARY OF THE INVENTION

Embodiments of the invention relate to busing sub-assemblies for photovoltaic modules and methods of forming photovoltaic modules using the same. The busing sub-assemblies generally include a carrier backsheet and a plurality of conductive ribbons coupled to the carrier backsheet. An electrically insulating cover having at least one opening therethrough is disposed over the conductive ribbons and the carrier backsheet. One end of each of the conductive ribbons is exposed through the at least one opening in the electrically insulating cover. Methods of forming photovoltaic modules generally include positioning a conductive foil on flexible backsheet having at least one opening therethrough. A busing sub-assembly is then disposed on the flexible backsheet over the opening and in electrical contact with the conductive foil. The busing sub-assembly includes a carrier backsheet, a plurality of conductive ribbons coupled to the carrier backsheet and an electrically insulating cover having an opening therethrough disposed over the conductive ribbons and the carrier backsheet. The busing sub-assembly includes the components necessary to bus electrical current from a plurality of solar cells to a junction box, and can be applied to a photovoltaic module in a single process step.

In one embodiment, a busing sub-assembly for a photovoltaic module comprises a carrier backsheet and a plurality of conductive ribbons adhered to the carrier backsheet. An electrically insulating cover is disposed over each of the plurality of conductive ribbons and in contact with the carrier backsheet. The electrically insulating cover is positioned at interior locations of each of the plurality of conductive ribbons such that each end portion of each of the plurality of conductive ribbons is exposed.

In another embodiment, a method of forming a photovoltaic module comprises positioning a flexible backsheet having an opening therethrough and a conductive foil thereon on a support. A busing sub-assembly is disposed on the flexible backsheet and over the opening through the flexible backsheet. The busing sub-assembly is in electrical contact with the conductive foil. The busing sub-assembly comprises a carrier backsheet, a first set of conductive ribbons adhered to the carrier backsheet, and an electrically insulating cover disposed over each conductive ribbon of the first set of conductive ribbons and in contact with the carrier backsheet. The electrically insulating cover is positioned at interior locations of each of the first set of conductive ribbons such that each end portion of each of the first set of conductive ribbons is exposed through the opening in the flexible backsheet.

In another embodiment, a method of forming a busing sub-assembly comprises positioning a carrier backsheet on a support, and screen printing an adhesive in a predetermined pattern on a front surface of the carrier backsheet. A plurality of conductive ribbons are then positioned on the adhesive and adhered to the carrier backsheet. An electrically insulating cover is then positioned over each of the plurality of conductive ribbons. The electrically insulating cover is positioned so that each end of each of the plurality of conductive ribbons is exposed.

In another embodiment, a photovoltaic module comprises a flexible backsheet having a layer of aluminum on a back surface thereof. The flexible backsheet has an opening therethrough. A conductive foil is adhered to a front surface of the flexible backsheet, and a plurality of solar cells are disposed on and electrically coupled to a surface of the conductive foil. A busing sub-assembly is disposed on the flexible backsheet over the opening therethrough. The busing sub-assembly comprises a carrier backsheet, and a plurality of conductive ribbons adhered to the carrier backsheet and spaced apart from one another. The plurality of conductive ribbons are adapted to be positioned in electrical contact with the conductive foil. The busing sub-assembly further comprises an electrically insulating cover disposed over each of the plurality of conductive ribbons and in contact with the carrier backsheet. The electrically insulating, cover is positioned adjacent to the opening through the flexible backsheet and adapted to prevent the plurality of conductive ribbons of the busing sub-assembly from contacting the aluminum layer of the flexible backsheet.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a front plan view of a flexible backsheet having a conductive foil and a plurality of solar cells coupled thereto.

FIG. 2 is a front plan view a busing sub-assembly according to one embodiment of the invention.

FIG. 3 is a front plan view a photovoltaic module having a flexible backsheet and a busing sub-assembly coupled thereto.

FIG. 4 illustrates a back plan view of the photovoltaic module shown in FIG. 3.

FIG. 5 is a front plan view of a busing sub-assembly according to another embodiment of the invention.

FIG. 6 illustrates a flow diagram of a method of forming a busing sub-assembly according to one embodiment of the invention.

FIG. 7 illustrates a flow diagram of a method of forming a photovoltaic module according to an embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention relate to busing sub-assemblies for photovoltaic modules and methods of forming photovoltaic modules using the same. The busing sub-assemblies generally include a carrier backsheet and a plurality of conductive ribbons coupled to the carrier backsheet. An electrically insulating cover having at least one opening therethrough is disposed over the conductive ribbons and the carrier backsheet. One end of each of the conductive ribbons is exposed through the at least one opening in the electrically insulating cover. Methods of forming photovoltaic modules generally include positioning a conductive foil on flexible backsheet having at least one opening therethrough. A busing sub-assembly is then disposed on the flexible backsheet over the opening and in electrical contact with the conductive foil. The busing sub-assembly includes a carrier backsheet, a plurality of conductive ribbons coupled to the carrier backsheet and an electrically insulating cover having an opening therethrough disposed over the conductive ribbons and the carrier backsheet. The busing sub-assembly includes the components necessary to bus electrical current from a plurality of solar cells to a junction box, and can be applied to a photovoltaic module in a single process step.

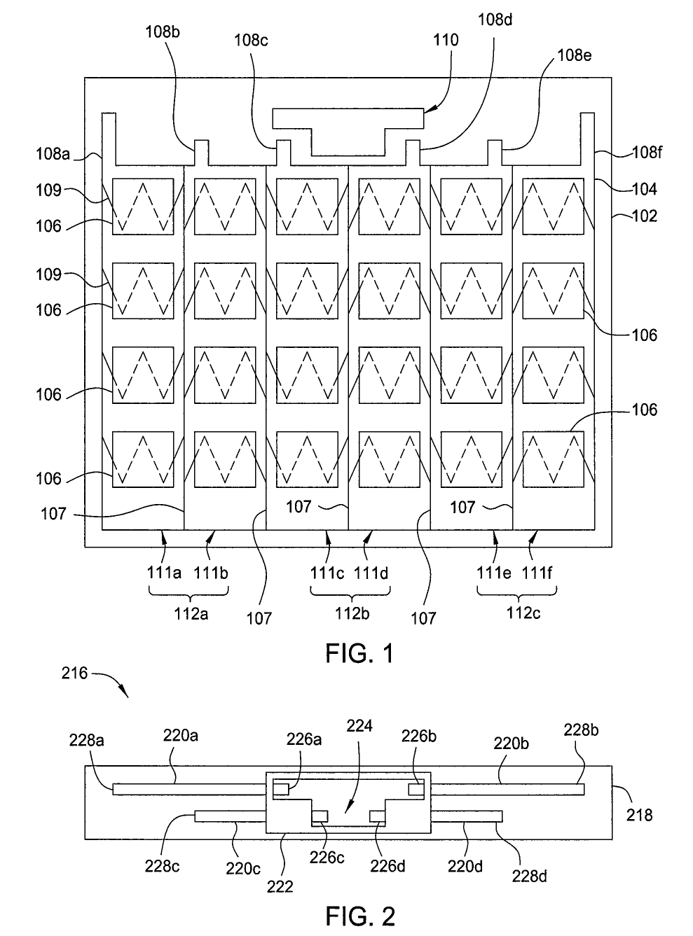

FIG. 1 is front plan view of a flexible backsheet 102 having a conductive foil 104 and a plurality of solar cells 106 coupled thereto. The flexible backsheet 102 is a multilayer structure. The front surface of the flexible backsheet 102 is formed from a layer of polyethelene terephthalate (PET) having a thickness within a range from about 100 microns to about 200 microns. The back surface of the flexible backsheet 102 is formed from a layer of aluminum which provides environmental protection to the conductive foil 104 and the solar cells 106. The layer of aluminum has a thickness of about 25 microns. An opening 110 is formed through the flexible backsheet 102 near one edge thereof. The opening 110 allows for electrically conductive elements to be passed therethrough for electrical connections to be made between elements located on opposite surfaces of the flexible backsheet 102. An adhesive (not shown), such as a pressure sensitive adhesive, is used to adhere the back surface of the conductive foil 104 to the front surface of the flexible backsheet 102. The conductive foil 104 has a generally rectangular shape and has conductive tabs 108a-108f positioned along the top edge of the conductive foil 104 near the opening 110 formed through the flexible backsheet 102.

The conductive foil 104 is formed from copper and has a thickness within a range form about 35 microns to about 70 microns. The conductive foil 104 is a sheet having grooves 107 and 109 formed therein. The grooves 107 and 109 are gaps formed within the conductive foil to separate and provide electrical isolation between portions of the conductive foil 104. The grooves 107 provide electrical isolation between each of the columns 111a-111f of solar cells 106. The grooves 109 provide electrical isolation between opposite conductivity portions of the conductive foil 104 in contact with the plurality of solar cells 106. The portions of the grooves 109 which are covered by the solar cells 106 are shown in phantom. The solar cells 106 are back contact solar cells; thus, both the positive polarity contacts and the negative polarity contacts of each solar cell 106 are positioned on the back surface of the solar cells 106 in electrical contact with the conductive foil 104. The grooves 109 are positioned between the positive and negative polarity contacts of the solar cells 106 to provide electrical isolation therebetween (e.g., the grooves 109 form a discontinuous surface in the conductive foil 104). Electrical current generated by the solar cells 106 is transported through the conductive foil 104 and solar cells 106 (over the grooves 109) in a series connection to a junction box or other location where the electric current can be utilized.

The solar cells 106 are arranged in three strings 112a-112c of eight solar cells 106 each. However, it is contemplated that the strings 112a-112c may contain more than eight solar cells each, for example about 20 solar cells or about 24 solar cells per string. Each string 112a-112c includes two columns or sets of four solar cells 106. String 112a includes columns 111a and 111b; string 112b includes columns 111c and 111d; and string 112c includes columns 111e and 111f. In order to electrically connect the strings 112a-112c to one another, and to electrically connect the two columns within each string 112a-112c to one another, busing ribbons (shown and discussed below) are used to bridge the grooves 107 and to form the electrical connection. Thus, the conductive foil 104 only forms an electrical connection (in series) within each column of solar cells 106; the conductive foil 104 does not electrically couple adjacent columns of solar cells 106 (due to grooves 107). The conductive tabs 108a-108f are positioned on the conductive foil 104 where busbars may be attached in order to form the electrical connection between the strings 112a-112c.

Although the conductive foil 104 is shown as having conductive tabs 108a-108f for coupling busbars thereto, other embodiments for making a connection between busbars and the conductive foil 104 are contemplated. In another embodiment, it is contemplated that the conductive foil 104 may lack the conductive tabs 108a-108f. In such an embodiment, the conductive foil 104 may have a rectangular shape, and the top portion of the conductive foil 104 may be covered with a dielectric material in a pattern which defines areas similar to the conductive tabs 108a-108f. Thus, conductive ribbons may be coupled to the areas near the top of the conductive foil which are not covered with the dielectric material.

FIG. 2 is schematic illustration of a busing sub-assembly 216 according to one embodiment of the invention. The busing sub-assembly 216 is adapted to be applied to a flexible backsheet during the formation of a photovoltaic module to provide busing connections within the photovoltaic module. The busing sub-assembly 216 includes a rectangular carrier backsheet 218, four conductive ribbons 220a-220d, and an electrically insulating cover 222. The four conductive ribbons 220a-220d are adhered to the upper surface of the carrier backsheet 218 by an adhesive (not shown), such as a pressure sensitive adhesive. The conductive ribbons 220a and 220b are positioned in a first row above the conductive ribbons 220c and 220d, which are positioned in a second row. The conductive ribbons 220a-220d are located in a spaced apart relationship from one another to allow electrical isolation therebetween. The conductive ribbons 220a-220d are positioned parallel to one another, however it contemplated that the orientation of the conductive ribbons 220a-220b may be different depending on the electrical contacts of the photovoltaic module into which the busing sub-assembly is to be positioned. The conductive ribbons 220a-220d are generally formed from copper and have a thickness within a range from about 35 microns to about 70 microns.

An electrically insulating cover 222, which is formed from polyester, is positioned over interior portions of the conductive ribbons 220a-220d and the carrier backsheet 218. The electrically insulating cover 222 has a rectangular outer edge and an opening 224 formed therethrough. The opening 224 has a shape corresponding to the opening 110 formed in the flexible backsheet 102 (shown in FIG. 1). The electrically insulating cover 222 is adhered to the carrier backsheet 218 and the conductive ribbons 220a-220d using an adhesive, such as a pressure sensitive adhesive. The electrically insulating cover 222 electrically insulates the conductive ribbons 220a-220d from the outer aluminum layer of a flexible backsheet when applied thereto. The interior ends 226a-226d of each of the conductive ribbons 220a-220d are exposed through the opening 224 formed in the electrically insulating cover 222. The distal ends 228a-228d are exposed and are spaced away from the electrically insulating cover 222. Thus, the electrically insulating cover 222 is positioned to cover portions of the conductive ribbons 220a-220d which are likely to contact an aluminum layer of a flexible backsheet when applied thereto. Although the electrically insulating cover 222 is described as being formed from polyester, other materials, such as electrically insulating tapes or encapsulants, may also be used to form the electrically insulating cover 222.

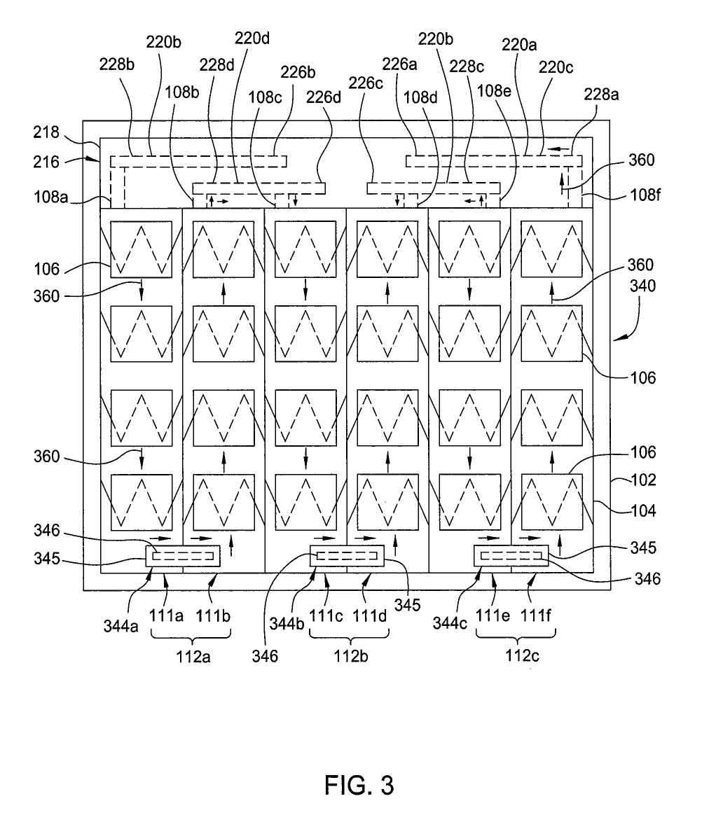

FIG. 3 is a front plan view a photovoltaic module 340 having a flexible backsheet 102 and a busing sub-assembly 216 coupled thereto. The front surface of the busing sub-assembly 216 is positioned on and in contact with the front surface of the flexible backsheet 102, such that the opening of the electrically insulating cover is aligned with the opening formed in the flexible backsheet 102. The conductive ribbons 220a-220d (shown in phantom) are located between the flexible backsheet 102 and the carrier backsheet 218. The distal end 228b of the conductive ribbon 220b is positioned over and in electrical contact with the conductive tab 108a (shown in phantom). The interior end 226b of the conductive ribbon 220b is positioned over the opening formed within the flexible backsheet 102. The opening formed within the backsheet is not shown in phantom for clarity purposes, however, it is to be understood that the opening is still present, but is covered by the busing sub-assembly 216. The distal end 228a of the conductive ribbon 220a is positioned over and in electrical contact with the conductive tab 108f (shown in phantom). The interior end 226a of the conductive ribbon 220a is positioned over the opening formed in the flexible backsheet 102.

The distal end 228d of the conductive ribbon 220d is positioned over and in electrical contact with the conductive tab 108b (shown in phantom). The interior end 226d of the conductive ribbon 220d is positioned over the opening formed within the flexible backsheet 102. The conductive tab 108c (shown in phantom) is also positioned in electrical contact with the conductive ribbon 220d. The conductive tab 108c contacts the conductive ribbon 220d at a location between the distal end 228d and the electrically insulating cover. The electrically insulating cover is not shown in phantom for clarity purposes; however, it is to be understood that the electrically insulating cover would located between the carrier backsheet 218 and the flexible backsheet 102.

The distal end 228c of the conductive ribbon 220c is positioned over and in electrical contact with the conductive tab 108e (shown in phantom). The interior end 226c of the conductive ribbon 220c is positioned over the opening formed within the flexible backsheet 102. The conductive tab 108d (shown in phantom) is also positioned in electrical contact with the conductive ribbon 220c. The conductive tab 108d contacts the conductive ribbon 220c at a location between the distal end 228c and the electrically insulating cover (e.g., the conductive tab 108d contacts the conductive ribbon 220c at a location laterally outward of the electrically insulating cover).

Lower busing assemblies 344a-344c are positioned over the conductive foil 104 to electrically couple column 111a to column 111b, column 111c to 111d, and column 111e to 111f, respectively. The lower busing assemblies 344a-344c include conductive ribbons 346 (shown in phantom) adhered to a lower busing assembly cover layer 345 using an adhesive, such as a pressure sensitive adhesive. The lower busing assembly cover layer 345 is generally formed from the same material as the carrier backsheet 218, for example, polyester. The lower busing assemblies 344a-344c are adhered to the conductive foil 104 by an adhesive located between the lower busing assembly cover layers 345 and the conductive foil 104. The conductive ribbons 346 of each of the lower busing assemblies 344a-344c are located between the lower busing assembly cover layer 345 and the flexible backsheet 102 adjacent to the adhesive when the lower busing assemblies 344a-344c are coupled to the photovoltaic module 340. The conductive ribbons 346 of the lower busing assemblies 344a-344c electrically couple the left column of solar cells 106 to the right column of solar cells 106 in each of the strings 112a-112c.

The flow of electrical current through the photovoltaic module 340 is illustrated by arrows 360 (only four of which are labeled for clarity). The electric current flows from the upper left solar cell 106 in column 111a and down the column 111a of string 112a. The current then flows through the conductive ribbon 346 of the lower busing assembly to the lower right solar cell 106 in the column 111b of the string 112a. The current flows up the column 111b of the string 112a and through a conductive ribbon 220d of the busing sub-assembly to the string 112b. The current then flows in a similar manner through the strings 112b and 112c. The current is removed from the photovoltaic module 340 after flowing up the right column of the string 112c, up the conductive tab 108f, through the conductive ribbon 220a and out of the back of the photovoltaic module to a junction box (not shown). Thus, the current flows in series through each of the solar cells 106 located in the photovoltaic module 340. It is to be noted that the direction of current flow in FIG. 3 is merely for illustrative purposes, and it is contemplated that the current flow may be reversed or follow a different path, as desired.

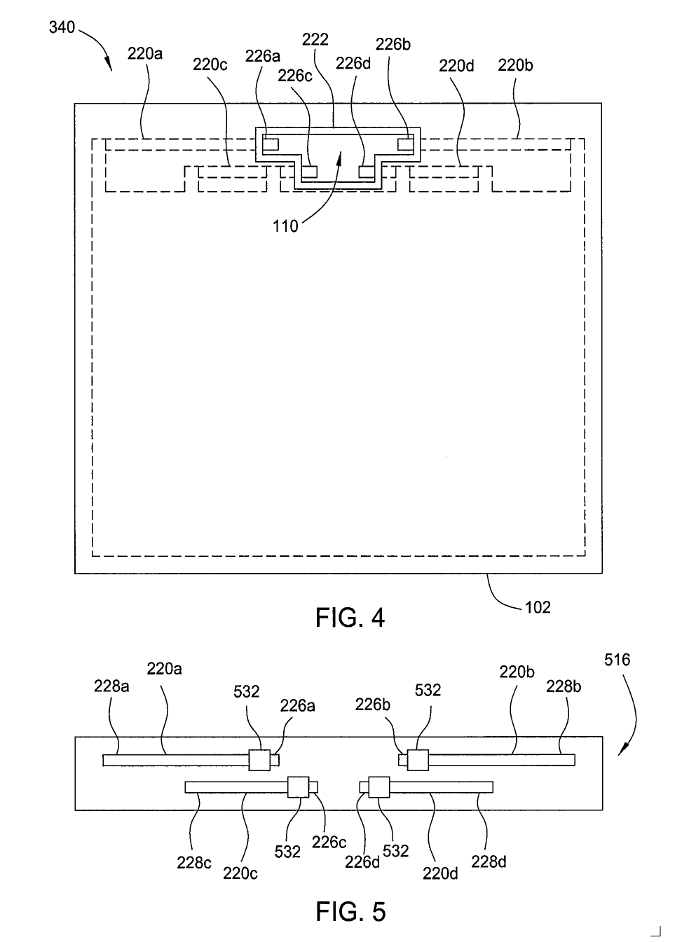

FIG. 4 illustrates a back plan view of the photovoltaic module shown in FIG. 3. FIG. 4 illustrates the opening 110 formed in the flexible backsheet 102. The opening 110 is positioned adjacent to the conductive foil 104 (shown in phantom), which is located on the front surface of the flexible backsheet 102. The electrically insulating cover 222 is disposed around the opening 110 and has an opening therethrough slightly smaller than the opening 110 formed in the flexible backsheet 102. Each of the interior ends 226a-226d of the conductive ribbons 220a-220d are exposed through the opening 110 to form an electrical connection thereto, for example, with a junction box. The portion of the electrically insulating cover 222 which overhangs the edges of the opening 110 (due to the smaller size of the opening in the electrically insulating cover 222) prevents interior ends 226a-226d from contacting the aluminum layer on the back surface of the flexible backsheet 102, which may be electrically grounded. Each of the interior ends 226a-226d are adapted to couple with another set of conductive ribbons (not shown) which are in electrical contact with a junction box. It is desirable to prevent contact of the aluminum layer of the flexible backsheet 102 with the interior ends 226a-226d or the conductive ribbons coupled thereto in order to reduce or prevent electrical shorts.

Although FIG. 4 is described with reference to coupling conductive ribbons to the interior ends 226a-226d to form a connection to a junction box, other embodiment are contemplated. For example, it is contemplated that the interior ends 226a-226d may extend through the opening 110 sufficiently far enough to be coupled directly to the junction box, and therefore, additional conductive ribbons would not be needed.

FIG. 5 is a front plan view of a busing sub-assembly 516 according to another embodiment of the invention. The busing sub-assembly 516 is similar to the busing sub-assembly 216, except the busing sub-assembly 516 does not include an electrically insulating cover formed from a unified piece of material. Instead, the busing sub-assembly 516 includes four discrete electrically insulating covers 532. One of each of the electrically insulating covers 532 is positioned over an interior location of each of the conductive ribbons 220a-220d to prevent electrical contact between the conductive ribbons 220a-220d and the aluminum layer of a flexible backsheet. The electrically insulating covers 532 are positioned over the conductive ribbons 220a-220d such that interior ends 226a-226d and distal ends 228a-228d are exposed in order to form an electrical connection thereto. The electrically insulating covers 532 are formed from an electrically insulating tape; however, it is contemplated that the electrically insulating covers may also be formed from polyester or an encapsulant material.

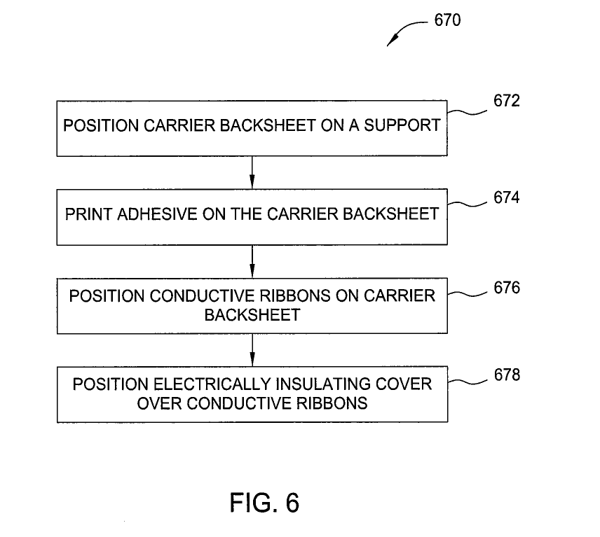

FIG. 6 illustrates a flow diagram 670 of a method of forming a busing sub-assembly according to one embodiment of the invention. In step 672 of flow diagram 670, a carrier backsheet, such as a rectangular sheet of polyester, is positioned front-surface-up on a support. The support may be a table or similar supporting surface having vacuum holes therethrough for maintaining the carrier backsheet in a predetermined positioned. Alternatively, the support may be plurality of rollers, such as a take-up roller and a feed roller, which are adapted to support the carrier backsheet in a roll-to-roll process. In step 674, after the carrier backsheet has been positioned on a support, an adhesive is applied to the front surface of the carrier backsheet in a predetermined pattern. The adhesive may be a pressure sensitive adhesive applied by screen printing; however, other adhesives, such as UV curable adhesives, and other application methods, such as rolling are contemplated. The predetermined pattern of adhesive generally corresponds to a pattern of conductive ribbons which are to be subsequently adhered to the surface of the carrier backsheet.

In step 676, a plurality of conductive ribbons are positioned on the predetermined pattern of adhesive and adhered to the carrier backsheet. The conductive ribbons may be positioned using a robot; thus, the placement of the conductive ribbons can be automated. The robot is adapted to apply sufficient pressure to the upper surface of the conductive ribbons after placement of the conductive ribbons when a pressure sensitive adhesive is utilized. Therefore, the robot not only positions the conductive ribbons, but activates the pressure sensitive adhesive as well. The plurality of conductive ribbons may be positioned on the carrier backsheet individually or simultaneously.

In step 678, an electrically insulating cover is positioned over each of the plurality of conductive ribbons using a robot. An adhesive, such as a pressure sensitive adhesive, may be applied to the back surface of the electrically insulating cover or to the front surface of the carrier backsheet prior to placement of the electrically insulating cover in order to bond the electrically insulating cover to the carrier backsheet. When using a pressure sensitive adhesive, the robot may also be adapted to apply sufficient pressure to the upper surface of the positioned electrically insulating cover to activate the pressure sensitive adhesive. After the electrically insulating material is adhered to the carrier backsheet, the busing sub-assembly may then be transported to a storage device, such as a magazine, for availability during a photovoltaic module formation process. Since the busing sub-assemblies can be formed at a different location than the photovoltaic modules, the assembly time required to form photovoltaic modules is decreased due to the pre-construction of the busing sub-assemblies at a separate location. Thus, during the formation of a photovoltaic module, the busing sub-assembly can be applied in a single process step, rather than applying each individual component of the busing assembly separately.

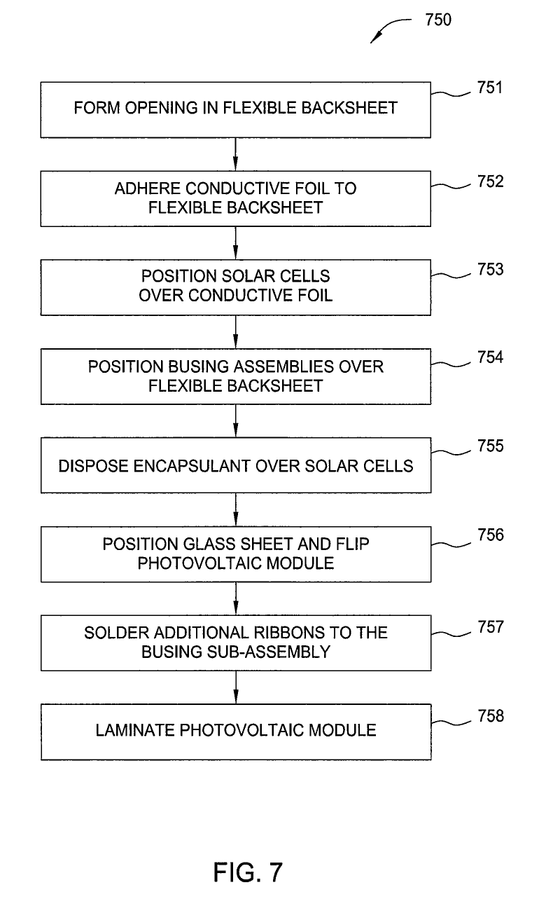

FIG. 7 illustrates a flow diagram 750 of a method of forming a photovoltaic module according to an embodiment of the invention. The flow diagram 750 begins at step 751. In step 751, an opening is formed through a flexible backsheet having a back surface formed from an aluminum layer and a front surface formed from a PET layer. The opening may be formed by cutting through the flexible backsheet using a saw or laser, or by punching through the flexible backsheet using a stamp or die set. In step 752, a conductive foil is adhered to the PET layer of the flexible backsheet below the opening formed through the backsheet. The conductive foil is adhered using an adhesive, such as a pressure sensitive adhesive, a temperature curable adhesive or an ultraviolet (UV) curable adhesive. The pressure sensitive adhesive is applied to the flexible backsheet by screen printing in a pattern corresponding to the conductive foil, and then the conductive foil is positioned on the adhesive using a robot having vacuum grippers adapted to hold the conductive foil during placement of the conductive foil.

In step 753, a plurality of solar cells are positioned over and in electrical contact with the conductive foil by a robot having a vacuum gripper coupled thereto. The plurality of solar cells are adhered to and electrically coupled with the conductive foil using a conductive adhesive, such as a metal containing paste. The conductive adhesive is screen printed on the conductive foil prior to placement of the solar cells. Additionally, a dielectric material, such as an acrylic or phenolic polymer material, may be disposed around the conductive adhesive by screen printing to provide electrical insulation between the solar cells and the conductive foil where desired. The dielectric material is also screen printed on the conductive foil prior to placement of the solar cells. It is contemplated that the dielectric material may be printed before or after the conductive adhesive.

In step 754, a busing sub-assembly is positioned near one edge of the flexible backsheet over the opening formed therethrough. Additionally, three lower busing assemblies are positioned near the bottom of the conductive foil. The busing sub-assembly and the three lower busing assemblies may be positioned using a robot adapted to pick and place the busing assemblies in electrical contact with the conductive foil. The robot allows for placement of the busing sub-assembly and the three lower busing assemblies to be automated. The busing sub-assembly and the three lower busing assemblies can be consistently positioned over the flexible backsheet by the robot, eliminating the need to manually position each busing ribbon by hand to ensure accurate alignment of the busing ribbons. Furthermore, manufacturing time of the photovoltaic module is greatly reduced because the busing components of the busing sub-assembly and the three lower busing assemblies can be positioned in single process step (because the busing assemblies include all the components necessary to bus current from the module). Positioning all the components of the busing assemblies in a single process step provides a significant time savings as compared to placing each component one at a time; such is as necessary when placing busing ribbons manually.

The front surfaces of the carrier backsheets of the busing sub-assembly and the three lower busing assemblies can include a pressure sensitive adhesive thereon to bond the busing sub-assembly and the three lower busing assemblies to the flexible backsheet and/or the conductive foil. The pressure sensitive adhesive sufficiently holds the conductive ribbons of the busing sub-assembly and the three lower busing assemblies against the conductive foil due to the adhesion between the carrier backsheets and flexible backsheet and/or conductive foil. Thus, the need to manually solder each individual conductive ribbon to the conductive foil, as is necessary during manual processing, is eliminated. The utilization of the busing sub-assembly and the three lower busing assemblies provides a significant time savings during the manufacturing of photovoltaic modules, due to the elimination of manual placement of individual busing ribbons, backsheets, and electrically insulating materials. The busing sub-assembly and the three lower busing assemblies allow for placement of busing components simultaneously in a single, automated process step.

In step 755, a sheet of encapsulant material, such as ethylene-vinyl acetate (EVA) is positioned over the solar cells and the conductive foil to eliminate air pockets in the photovoltaic module during a subsequent module lamination process. The sheet of encapsulant material is generally sized to cover all of the solar cells and is positioned over the solar cells using a robot. In step 756, a glass sheet is positioned over the encapsulant material and provides environmental protection to the photovoltaic module. The glass sheet is positioned using a robot having vacuum grippers adapted to secure the glass sheet during transportation and adapted to position the glass sheet over the encapsulant material. After placement of the glass sheet, the photovoltaic module is then flipped using a robot such that the glass sheet is positioned in contact with the support. During the flipping process of the photovoltaic module, the robot clamps two opposing edges of the photovoltaic module with grippers and applies sufficient pressure to prevent inadvertent movement of the photovoltaic module components. The two grippers, which are positioned coaxially, lift the photovoltaic module vertically, flip the photovoltaic module 180 degrees, and reposition the photovoltaic module back on a support.

In step 757, a set of conductive ribbons is attached to the conductive ribbons of the busing sub-assembly exposed through the opening in the flexible backsheet. The set of conductive ribbons is attached to the conductive ribbons of the busing sub-assembly from the back surface of the photovoltaic module. The set of conductive ribbons provides an electric path from the conductive foil on the front surface of the module, thorough the opening in the flexible backsheet to the back surface of the module. Each ribbon in the set of conductive ribbons is generally connected to one of the conductive ribbons of the busing sub-assembly by soldering. Each ribbon in the set of conductive ribbons is then connected to a junction box, which includes a plurality of diodes therein. The junction box is adapted to collect electric current generated in the photovoltaic module.

In step 758, the photovoltaic module is laminated using a heating and/or pressure process. During the lamination process, the encapsulant is heated to a sufficient temperature to become fluid and flow into the spaces within the photovoltaic module, including the opening in the backsheet, thus eliminating any air gaps within the photovoltaic module. The encapsulant surrounds the conductive ribbons of the busing sub-assembly, as well as the set of conductive ribbons soldered thereto, thus providing electrical isolation therebetween. During the lamination process, heat may be applied using one or more lamps, while pressure may be provided by an actuatable arm adapted to contact and press against the photovoltaic module.

Flow diagram 750 illustrates one embodiment of forming a photovoltaic module; however, other embodiments are contemplated. In another embodiment, it is contemplated that step 754 may occur before step 753. In yet another embodiment, it is contemplated that pressure sensitive adhesive may not be utilized in step 754 to adhere the carrier backsheets of the busing sub-assembly and the three lower busing assemblies to the flexible backsheet. Instead, a conductive adhesive may be applied to either the conductive foil or the conductive ribbons of the busing sub-assembly and the three lower busing assemblies to form a bond therebetween. In yet another embodiment, it is contemplated that step 757 may be excluded. Instead, the conductive ribbons of the busing sub-assembly may have a length sufficient to be pulled through the opening of the flexible backsheet and connected to a junction box.

Additionally, although embodiments herein generally refer to a flexible backsheet including a layer of PET, other flexible backsheet materials are contemplated. For example, it is contemplated that the flexible backsheet may be formed from polyvinyl fluoride, polyester, polyimides, or polyethylene. Additionally, although the conductive foil 104 is generally formed from copper, it is contemplated that other materials, including aluminum or copper clad aluminum, may be used to form the conductive foil 104.

Benefits of the present invention include a busing sub-assembly having the components necessary to bus electrical current from a plurality of solar cells to a junction box. The busing sub-assembly can be applied to a photovoltaic module in a single process step rather than applying individual busing components manually. The busing sub-assembly eliminates the need for time-intensive manual placement of the busing ribbons, thus improving throughput and lowering manufacturing costs.

While the foregoing is directed to embodiments of the present invention, other and further embodiments of the invention may be devised without departing from the basic scope thereof, and the scope thereof is determined by the claims that follow.

We claim:

1. A busing sub-assembly for a photovoltaic module, comprising:
a carrier backsheet;
a plurality of conductive ribbons adhered to the carrier backsheet and spaced apart from one another; and
an electrically insulating cover disposed over each of the plurality of conductive ribbons and in contact with the carrier backsheet, the electrically insulating cover positioned at interior locations of each of the plurality of conductive ribbons such that each end portion of each of the plurality of conductive ribbons is exposed.

2. The busing sub-assembly of claim 1, wherein the plurality of conductive ribbons comprise copper.

3. The busing sub-assembly of claim 1, wherein the electrically insulating cover comprises a sheet of polyester.

4. The busing sub-assembly of claim 1, wherein the electrically insulating cover comprises electrically insulating tape.

5. The busing sub-assembly of claim 4, wherein:
an end portion of each of the plurality of conductive ribbons extends through the electrically insulating cover and has a sufficient length to be coupled to a junction box when the busing sub-assembly is positioned in a photovoltaic module; and
the electrically insulating cover comprises a single piece of material disposed over all of the plurality of conductive ribbons.

6. The busing sub-assembly of claim 1, wherein a discrete electrically insulating cover is disposed over each of the conductive ribbons of the plurality of conductive ribbons.

7. The busing sub-assembly of claim 1, wherein the carrier backsheet comprises polyester.

8. A method of forming a photovoltaic module, comprising:
positioning a conductive foil on a flexible backsheet having an opening therethrough;
disposing a busing sub-assembly on the flexible backsheet and over the opening through the flexible backsheet, the busing sub-assembly positioned in electrical contact with the conductive foil, the busing sub-assembly comprising:
a carrier backsheet;
a first set of conductive ribbons adhered to the carrier backsheet; and
an electrically insulating cover disposed over each conductive ribbon of the first set of conductive ribbons and in contact with the carrier backsheet, the electrically insulating cover positioned at interior locations of each of the first set of conductive ribbons such that each end portion of each of the first set of conductive ribbons is exposed through the opening in the flexible backsheet.

9. The method of claim 8, further comprising:
connecting a second set of conductive ribbons to the end portion of each of the first set of conductive ribbons exposed through the opening in the flexible backsheet; and
coupling each of the second set of conductive ribbons to a junction box.

10. The method of claim 8, wherein the conductive foil has a plurality of solar cells electrically coupled thereto, and wherein plurality of solar cells are coupled to the conductive foil after disposing the busing sub-assembly on the flexible backsheet.

11. The method of claim 8, wherein the conductive foil has a plurality of solar cells electrically coupled thereto, and wherein plurality of solar cells are coupled to the conductive foil prior to disposing the busing sub-assembly on the flexible backsheet.

12. The method of claim 8, wherein the flexible backsheet comprises an aluminum layer adhered to the outer surface thereof, and wherein the electrically insulating cover of the busing sub-assembly electrically insulates the first set of conductive ribbons from the aluminum layer.

13. The method of claim 8, further comprising:
coupling a plurality of solar cells to the conductive foil;
disposing an encapsulant over the plurality of solar cells;
disposing a glass cover over the plurality of solar cells and the encapsulant; and
laminating the glass cover to the flexible backsheet, wherein the laminating increases the temperature of the encapsulant to a fluid state, and the encapsulant flows to a position around the first set of conductive ribbons and within the opening of the backsheet during the lamination process.

14. The method of claim 8, wherein the electrically insulating cover of the busing sub-assembly has a shape corresponding to the opening through the flexible backsheet.

15. The method of claim 8, wherein the flexible backsheet, the carrier backsheet, and the electrically insulating cover each comprise polyester.

16. The method of claim 8, wherein the first set of conductive ribbons extends through the opening in the flexible backsheet after disposing the busing sub-assembly on the flexible backsheet.

17. A photovoltaic module, comprising:
a flexible backsheet having a layer of aluminum on a back surface thereof, the flexible backsheet having an opening therethrough;
a conductive foil adhered to a front surface of the flexible backsheet;
a plurality of solar cells disposed on and electrically coupled to a surface of the conductive foil;
a busing sub-assembly disposed on the flexible backsheet over the opening therethrough, the busing sub-assembly comprising:
a carrier backsheet;
a plurality of conductive ribbons adhered to the carrier backsheet and spaced apart from one another, the plurality of conductive ribbons adapted to be positioned in electrical contact with the conductive foil; and
an electrically insulating cover disposed over each of the plurality of conductive ribbons and in contact with the carrier backsheet, the electrically insulating cover positioned adjacent to the opening through the flexible backsheet and adapted to prevent the plurality of conductive ribbons of the busing sub-assembly from contacting the aluminum layer of the flexible backsheet.

18. The photovoltaic module of claim 17, wherein the end portion of each of the plurality of conductive ribbons extends through an opening formed in the electrically insulating cover and has a sufficient length to be coupled to a junction box.

19. The photovoltaic module of claim 17, wherein the electrically insulating cover comprises a single piece of material disposed over all the plurality of conductive ribbons.

20. The photovoltaic module of claim 17, wherein a discrete electrically insulating cover is disposed over each of the conductive ribbons of the plurality of conductive ribbons.
